(19) United States
(12) Patent Application Publication
(10) Pub. No.: US 2007/0056925 A1
(43) Pub. Date: Mar. 15, 2007

(54) Selective etch of films with high dielectric constant with H2 addition

(75) Inventors: Shenjian Liu, Fremont, CA (US); Linda Fung-Ming Lee, Redwood City, CA (US); Anthony Chen, Pleasanton, CA (US)

Correspondence Address: BEYER WEAVER LLP, P.O. BOX 70250, OAKLAND, CA, 94612-0250, US

(73) Assignee: Lam Research Corporation

(21) Appl. No.: 11/223,780

(22) Filed: Sep. 9, 2005

(51) Int. Cl. C23F 1/00; H01L 21/306; H01L 21/302; B44C 1/22

(52) U.S. Cl. 216/67; 438/710; 156/345.33

(57) ABSTRACT

A method for selectively etching a high k layer with respect to a silicon based material is provided. The high k layer is placed into an etch chamber. An etchant gas is provided into the etch chamber, wherein the etchant gas comprises H₂. A plasma is generated from the etchant gas to selectively etch the high k layer with respect to a silicon based material.

### BACKGROUND OF THE INVENTION

1. Field of the Invention

The invention relates to semiconductor devices. More specifically, the invention relates to semiconductor devices with a layer of a high dielectric constant material.

2. Description of the Related Art

Since, flash memory is widely used in portable electronic devices, such as laptop computers, mobile phones, PDAs, etc, the demand to reduce operation voltage, so as to reduce energy consumption has been ever increasing.

An ONO (oxide nitride oxide) layer has been used in flash memory device gate stack for memory storage. However, the dielectric constant of ONO is not enough to meet the ever increasing demand in operation voltage, so high dielectric constant material (or referred as to high k material) has been introduced to replace ONO.

The dielectric constant of SiO₂ is about 3.9. If high k material like Al₂O₃ is used to replace SiO₂, the dielectric constant will increase to around 9.0. Other than Al₂O₃, HfO₂, Ta₂O₃ are also considered as the candidates for high k materials in flash memory gate stack to replace ONO. Among them, Al₂O₃, HfO₂ and Al₂O₃/HfO₂/Al₂O₃ sandwich structure have been used.

Etching of high k material has been found to be more difficult compared to etching ONO, because of lower volatility of its etch byproduct. Because of this, the etch rate, and the its selectivity to polysilicon film has been found to be much lower compared to ONO film. Efforts have been made to increase the etch rate and selectivity of high k material to polysilicon.

### SUMMARY OF THE INVENTION

To achieve the foregoing and in accordance with the purpose of the present invention, a method for selectively etching a high k layer with respect a silicon based material is provided. The high k layer over a silicon based layer is placed into an etch chamber. An etchant gas is provided into the etch chamber, wherein the etchant gas comprises H₂. A plasma is generated from the etchant gas to selectively etch the high k layer with respect to the silicon based material.

In another manifestation of the invention, a method for etching a stack with a high k layer over a silicon based layer is provided. The stack is placed into an etch chamber. The high k layer is selectively etched with respect to the silicon based layer. The selective etching comprises providing a high k layer etchant gas into the etch chamber, wherein the high k layer etchant gas comprises H₂ and generating a plasma from the high k layer etchant gas to selectively etch the high k layer with respect to the silicon based layer

In another manifestation of the invention, an apparatus for forming flash memory with a high k dielectric layer over a silicon based layer is provided. A plasma processing chamber, comprising a chamber wall forming a plasma processing chamber enclosure, a substrate support for supporting a substrate within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure is provided. A gas source is in fluid connection with the gas inlet and comprises an H₂ gas source, a BCl₃ gas source, and a Cl₂ gas source. A controller is controllably connected to the gas source and the at least one electrode and comprises at least one processor and computer readable media. The computer readable media comprises computer readable code for selectively etching the high k layer with respect to the silicon based layer, computer readable code to stop the selectively etching the high k layer with respect to the silicon based layer, and computer readable code for selectively etching the silicon based layer with respect to the high k layer. The computer readable code for selectively etching the high k layer with respect to the silicon based layer comprises computer readable code for providing H₂ from the H₂ gas source, computer readable code for providing BCl₃ from the BCl₃ gas source, computer readable code for providing Cl₂ from the Cl₂ gas source, and computer readable code for generating a plasma from the H₂, BCl₃, and Cl₂ to selectively etch the high k layer with respect to the silicon based layer.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a schematic view of a field effect transistor that may be formed using an embodiment of the invention.

FIG. 2 is a flow chart of a process used in an embodiment of the invention.

FIGS. 3A-3D are schematic cross-sectional views of a high dielectric constant layer formed according to the invention.

FIG. 4 is a schematic view of a process chamber that may be used in a preferred embodiment of the invention.

FIGS. 5A and 5B illustrate a computer system, which is suitable for implementing a controller.

FIG. 6 is a flow chart of a process used in another embodiment of the invention to form flash memory.

FIGS. 7A-7G are schematic cross-sectional views of the formation of a flash memory device formed according to the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

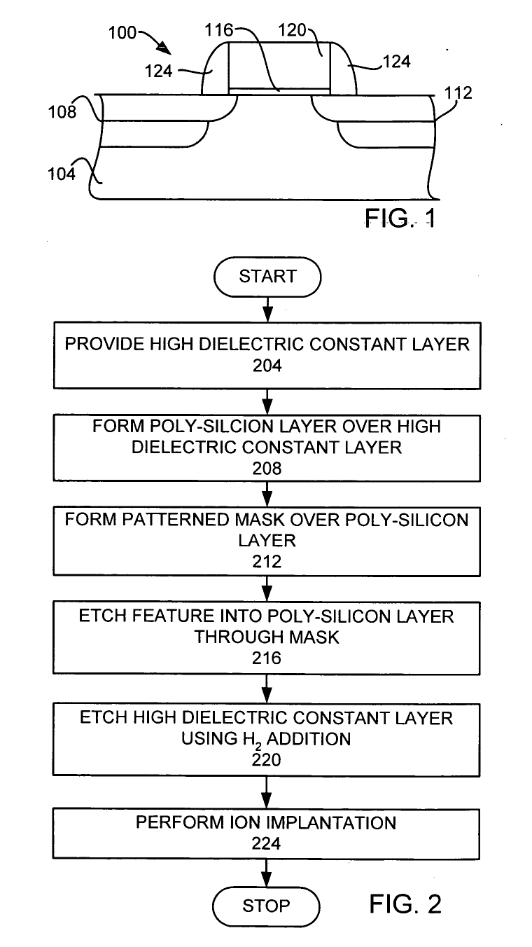

To facilitate understanding, FIG. 1 is a schematic view of a field effect transistor 100. The field effect transistor 100 comprises a substrate 104 into which a source 108 and a drain 112 are doped. A gate oxide 116 is formed over the substrate. A gate electrode 120 is formed over the gate oxide 116, so that the gate oxide 116 forms an insulator between the gate electrode 120 and the channel in the substrate 104 below the gate oxide 116. Spacers 124 are place at ends of the gate electrode 120 and the gate oxide 116. The invention provides a selective etch that allows the gate oxide 116 to be formed from a high dielectric constant material.

In the specification and claims, a high dielectric constant material has a dielectric constant of at least 8 (K≧8).

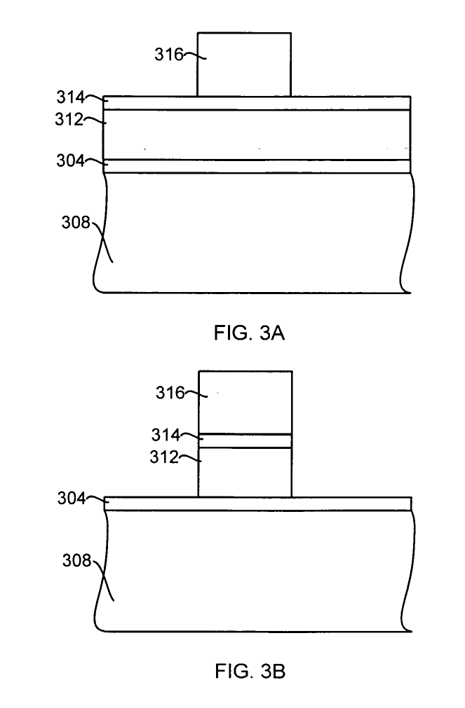

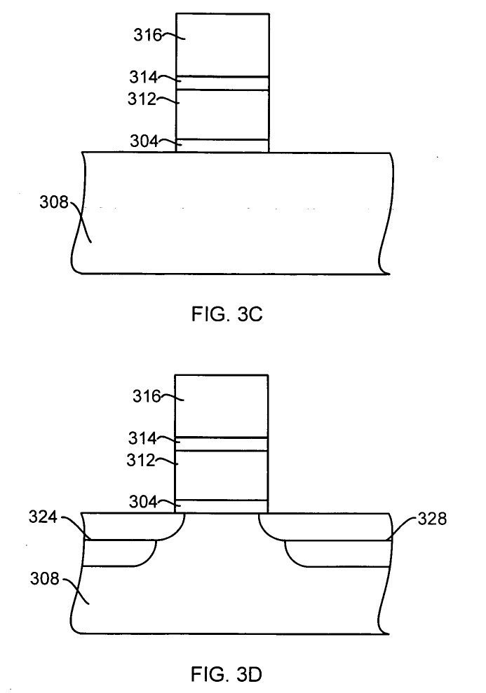

FIG. 2 is a high level flow chart for forming a semiconductor device with a high dielectric constant layer. A layer of high dielectric constant (high k) material is provided over a substrate (step 204). Atomic layer deposition, sputtering or chemical vapor deposition may be used to deposit the layer of high dielectric constant material. FIG. 3A is a schematic cross-sectional view of a high dielectric constant layer 304 that has been deposited over a substrate 308. The substrate is a silicon based material. Preferably, the silicon based material is substantially crystalline silicon, which may be part of a silicon wafer, or if the semiconductor device is several layers above the wafer, the silicon substrate may be a polysilicon.

A poly-silicon layer 312 is then formed over the high k layer 304 (step 208). A patterned mask 316, such as a photoresist mask is placed over the poly-silicon layer 312 (step 212). An antireflective coating 314 may be between the patterned mask 316 and the poly-silicon layer 312, to facilitate the formation of the patterned mask 316. The poly-silicon layer 312 is then etched through the mask (step 216). FIG. 3B is a schematic cross-sectional view after the poly-silicon layer 312 has been etched.

The high k layer 304 is then etched using an H₂ addition (step 220), as shown in FIG. 3C. It is desirable that the etch of the high dielectric constant layer 304 be highly selective so as to minimize the etching the underlying substrate 308 and minimize the etching of the poly-silicon layer 312. In the preferred embodiment, the etch is so highly selective that less than 5 Å of the substrate is removed during the etching of the high dielectric constant layer 304.

An ion implantation is performed (step 224) to create the source and drain regions. FIG. 3D is a schematic view after the source regions 324 and drain regions 328 have been formed. Since ion implantation is highly dependent on the characteristics of the substrate, to provide uniform source and drain regions across a wafer, the etching of the substrate must be minimized.

U.S. Pat. No. 6,511,872, by Donnelly, Jr. et al., issued Jan. 28, 2003 discloses a method of etching a high dielectric constant layer over a substrate. An etch chemistry of BCl₃ and Cl₂ is disclosed. However, a process with a high etch selectivity of the high k dielectric layer to substrate is not disclosed. The article “Etching of high-k dielectric Zr₁₋ₓAlₓO_{y} films in chlorine-containing plasmas” by K. Pelhos et al., published in the Journal of Vacuum Science Technology A 19(4) July/August 2001 pp. 1361-1366 discusses the same etch chemistry and also does not disclose a process with a high etch selectivity.

The article “Plasma Etching Selectivity of ZrO₂ to Si in BCl₃/Cl₂ Plasmas,” by Lin Sha and Jane P. Chang, in the Journal of Vacuum Science Technology A 21(6) July/August 2001 pp. 1915-1922 discloses a method of etching a high dielectric constant layer over a substrate. An etchant chemistry of BCl₃, Cl₂ and 5% Ar is disclosed. This article states that the highest etch selectivity of 1.5 was reached by using pure BCl₃. It is desirable to have higher etch selectivities to minimize the etching of the substrate.

In a preferred embodiment of the invention, the high dielectric constant layer may be formed from a material with a dielectric constant of at least 8, such as Hf silicate (K≅11), HfO₂ (K≅25-30), Zr silicate (K≅11-13), ZrO₂ (K≅22-28), Al₂O₃ (K≅8-12)), La₂O₃ (K≅25-30), SrTiO₃ (K≅200), SrZrO₃ (K≅25), TiO₂ (K≅80), and Y₂O₃ (K≅8-15), which are oxides. More preferably, the high dielectric constant layer is a binary metal oxide.

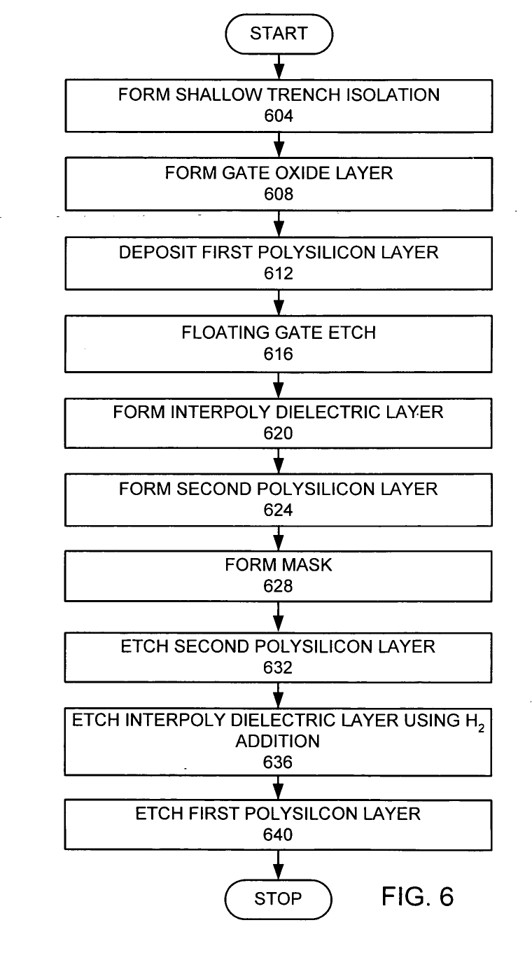

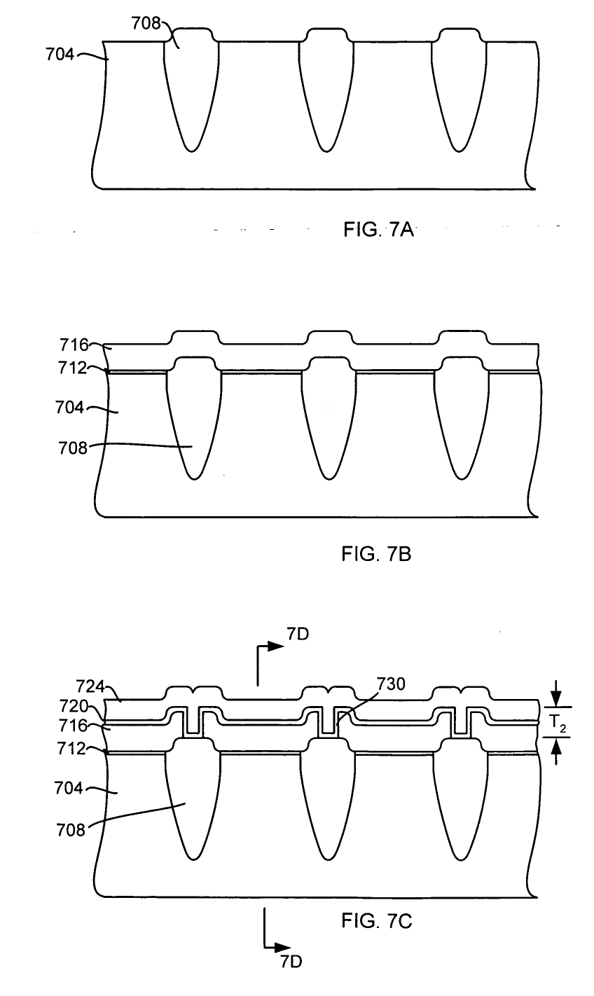

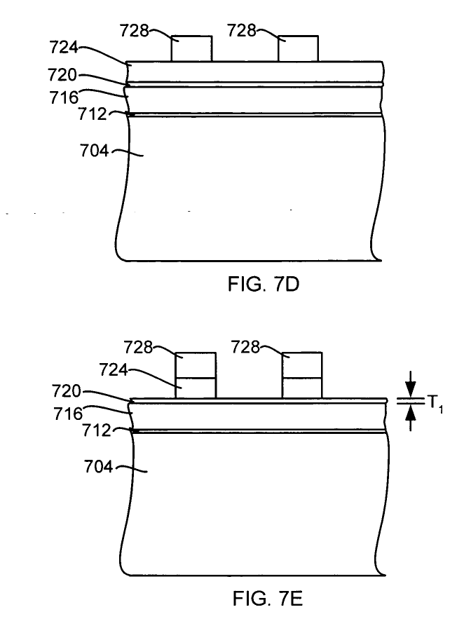

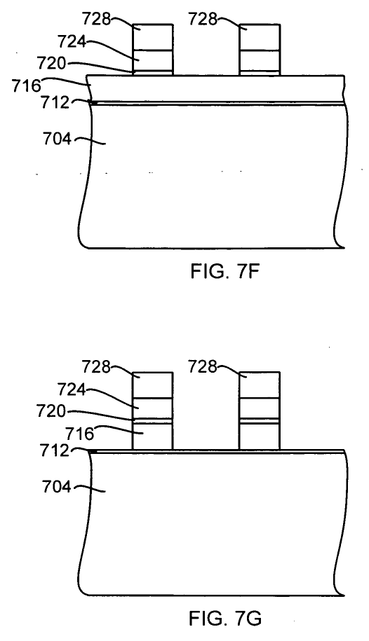

FIG. 6 is a high level flow chart for forming a flash memory device with a high dielectric constant layer. Shallow trench isolation regions are formed in a substrate (step 604). FIG. 7A is a schematic cross-sectional view of a substrate 704 with a three shallow trench isolation regions 708.

A gate oxide layer is formed (step 608). FIG. 7B shows a gate oxide layer 712 formed over the surface of the substrate 704. The gate oxide layer 712 may be formed by exposing the substrate 704 to oxygen. A first polysilicon layer 716 is then deposited over the shallow trench isolation regions 708 and gate oxide 712.

A floating gate etch is performed (step 616) to etch the first polysilicon layer 716, to the form as shown in FIG. 7C. An interpoly dielectric layer (IPD) 720 is formed over the etched first polysilicon layer 716. The IPD layer 720 is of a high k dielectric material. A second polysilicon layer 724 is formed over the IPD layer 720 (step 628).

A mask is formed over the second polysilicon layer (step 628). FIG. 7D is a cross-sectional view of the substrate 704 of FIG. 7C along cut lines 7D-7D, after the mask 728 has been formed over the second polysilicon layer 724, as shown. The mask 728 is used to etch the second polysilicon layer 724, to obtain the stack formation, as shown in FIG. 7E.

The interpoly dielectric layer 712 is etch using an H₂ addition (step 636), as shown in FIG. 7F. The etching of the IPD layer 712 provides a challenge, since the IPD layer thickness may significantly vary. For example, comparing the thickness T₁ of the IPD layer, as shown in FIG. 7E to the thickness T₂ of the columns 730 of the IPD layer as shown in FIG. 7C, T₂ may be more than three times greater than T₁. Incomplete etching of the IPD layer columns 730 forms stringers, which are undesirable. An improper etch to eliminate the stringers causes etching of the first polysilicon layer 716, which could cause damage. In addition, if the first polysilicon layer 716 is etch through during the improper etching to eliminate the IPD layer stringers the gate oxide layer 608 will be damaged. The use of an etch with an H₂ addition allows such a highly selective etch of the high k IPD layer 720 with respect to the polysilicon layer 716, the stringers are removed without damaging the flash memory structure. The first polysilicon layer 716 is then etched, as shown in FIG. 7G (step 640). Preferably, the first polysilicon layer 716 is selectively etched with respect to the high k layer. Additional steps may be used to complete the flash memory structure.

Example of High k Dielectric Etch

In an example of the high k dielectric etch, during the high k layer etch using an H₂ addition (steps 220 and 636), the wafer is placed in an etch chamber. The etch chamber may be used for etching the poly-silicon layer (step 216) or a different chamber may be used to for etching the poly-silicon layer.

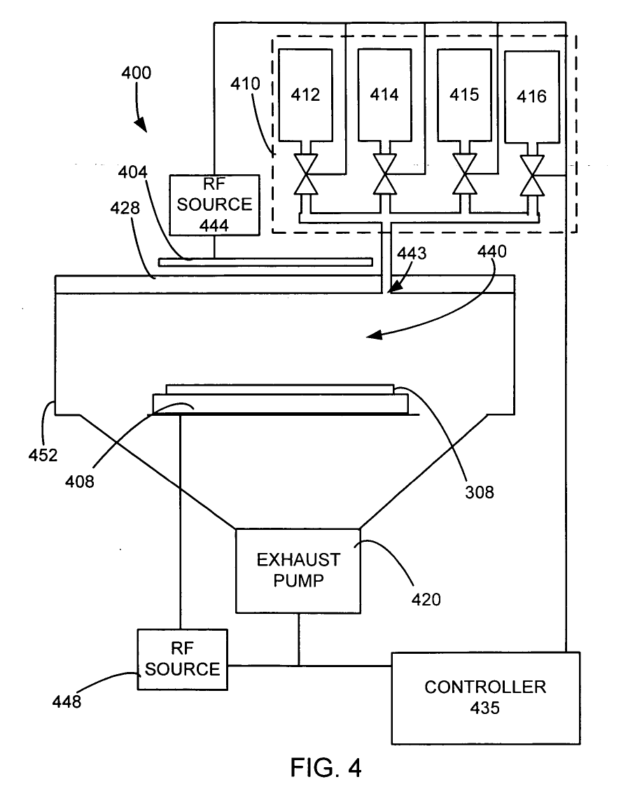

FIG. 4 is a schematic view of a process chamber 400 that may be used in the preferred embodiment of the invention. In this embodiment, the plasma processing chamber 400 comprises an inductive coil 404, a lower electrode 408, a gas source 410, and an exhaust pump 420. Within plasma processing chamber 400, the substrate 308 is positioned upon the lower electrode 408. The lower electrode 408 incorporates a suitable substrate chucking mechanism (e.g., electrostatic, mechanical clamping, or the like) for supporting the substrate 308. The reactor top 428 incorporates a dielectric window. The reactor top 428, chamber walls 452, and lower electrode 408 define a confined plasma volume 440. Gas is supplied to the confined plasma volume by gas source 410 through a gas inlet 443 and is exhausted from the confined plasma volume by the exhaust pump 420. The exhaust pump 420 forms a gas outlet for the plasma processing chamber. A first RF source 444 is electrically connected to the coil 404. A second RF source 448 is electrically connected to the lower electrode 408. In this embodiment, the first and second RF sources 444, 448 comprise a 13.56 MHz power source. Different combinations of connecting RF power to the electrodes are possible. A controller 435 is controllably connected to the first RF source 444, the second RF source 448, the exhaust pump 420, and the gas source 410. In this example the process chamber is a Versys 2300 built by Lam Research Corporation of Fremont Calif. Both the bottom and top RF sources provide a power signal at a frequency of 13.56 MHz.

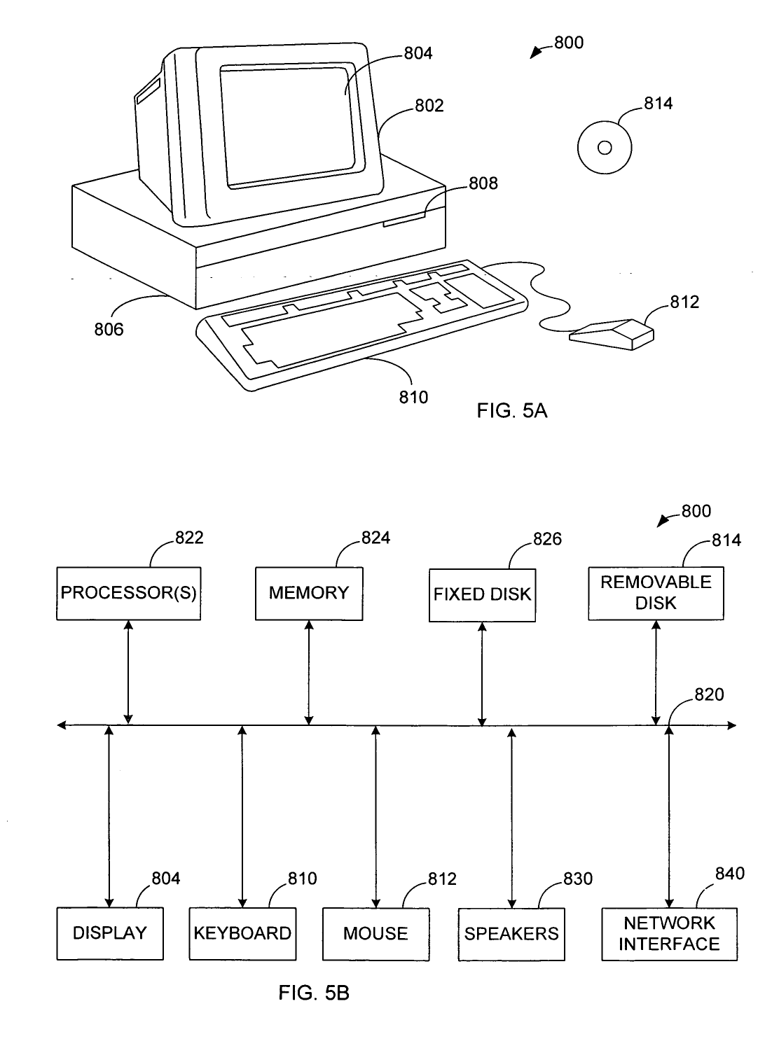

FIGS. 5A and 5B illustrate a computer system 800, which is suitable for implementing a controller 435 used in embodiments of the present invention. FIG. 5A shows one possible physical form of the computer system. Of course, the computer system may have many physical forms ranging from an integrated circuit, a printed circuit board, and a small handheld device up to a huge super computer. Computer system 800 includes a monitor 802, a display 804, a housing 806, a disk drive 808, a keyboard 810, and a mouse 812. Disk 814 is a computer-readable medium used to transfer data to and from computer system 800.

FIG. 5B is an example of a block diagram for computer system 800.

Attached to system bus 820 is a wide variety of subsystems. Processor(s) 822 (also referred to as central processing units or CPUs) are coupled to storage devices, including memory 824. Memory 824 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 826 is also coupled bi-directionally to CPU 822; it provides additional data storage capacity and may also include any of the computer-readable media described below.

Fixed disk 826 may be used to store programs, data, and the like and is typically a secondary storage medium (such as a hard disk) that is slower than primary storage. It will be appreciated that the information retained within fixed disk 826 may, in appropriate cases, be incorporated in standard fashion as virtual memory in memory 824. Removable disk 814 may take the form of any of the computer-readable media described below.

CPU 822 is also coupled to a variety of input/output devices, such as display 804, keyboard 810, mouse 812, and speakers 830. In general, an input/output device may be any of video displays, track balls, mice, keyboards, microphones, touch-sensitive displays, transducer card readers, magnetic or paper tape readers, tablets, styluses, voice or handwriting recognizers, biometrics readers, or other computers. CPU 822 optionally may be coupled to another computer or telecommunications network using network interface 840. With such a network interface, it is contemplated that the CPU might receive information from the network, or might output information to the network in the course of performing the above-described method steps. Furthermore, method embodiments of the present invention may execute solely upon CPU 822 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

An etchant gas of BCl₃, and inert diluent, Cl₂, and an H₂ addition is provided from the gas source 410 to the area of the plasma volume. The inert diluent may be any inert gas such as neon, argon, or xenon. More preferably, the inert diluent is argon. Therefore, the gas source 410 may comprise a BCl₃ source 412, a Cl₂ source 414, an H₂ source 415, and an argon source 416. The controller 435 is able to control the flow rate of the various gases.

In this example, the etchant gas the etchant gas consists essentially of BCl₃, Cl₂, Ar, CₓH_{y}, and H₂. Preferably the total gas flow is 5-1,000 sccm, where the ratio by volume of Cl₂ to BCl₃ is 0-2:1, the ratio by volume of H₂ to BCl₃ is 0.2-5:1, and the ratio by volume of CₓH_{y} to BCl₃ is 0-0.5:1, and the flow of the Ar or another inert gas is between 0-500 sccm. The etch was done with about 200% over etch and the polysilicon loss after this is about 100 A. The thickness of high k material is about 250 A, so 200% over etch is equivalent to 500 A of high k dielectric etch. Based on above, the high k to polysilicon etch selectivity is estimated at about 5.

In this example, the high k dielectric is Al₂O₃ is over a polysilicon. The gas source 410 provides an etchant gas comprising BCl₃, argon, Cl₂, and an H₂ addition to the process chamber. During the etch, the wafer is maintained at a temperature between 20°-80° C. Although other methods may require a high temperature, which requires heating, to provide a selective etch, the invention may be performed without heating the wafer, which prevents thermal damage to the wafer. In addition, the lower temperatures create less problems than methods that require that the wafer is heated. The controller 435 controls the exhaust pump 448 and gas source 410 to control the chamber pressure. The chamber pressure is maintained between 2-20 mTorr, during the etch.

A D.C. bias may be applied to the lower electrode. Preferably, the absolute value of the D.C. bias is between 0-300 volts. Most preferably, the absolute value of the D.C. bias is less than 50 volts. Preferably, the upper RF source provides a power of 200-1400 Watts (TCP) through the coil 404 to the etch chamber at a frequency of about 13.56 MHz. As a result, a plasma density of 10⁹-10¹¹ ions/cm³ is provided.

The effect of inert gas addition is to increase of the sputtering so that no residue is formed during the etch. Another effect of inert gas dilution is to improve etch rate uniformity.

The ratio of BCl₃ to Cl₂ allows Cl₂ to clean up deposits from the BCl₃, which prevents the formation of footers in a tapered etch, without significantly sacrificing selectivity.

Without wishing to be bound by theory, it is also believed that the use of a lower chamber pressure and high TCP cause high dissociation of BCl₃ and BCl₂⁺. It is further believed that the more further dissociated species provides the desired etching.

The H₂ addition is believed to both increase the Al₂O₃ etch rate and decrease the polysilicon etch rate. Without being bound by theory, it is believed that the H₂ addition facilitates the dissociation of Al₂O₃ into Al³⁺ and O²⁻ to increase the etch rate of the high k dielectric. In addition, the H₂ forms passivation on the polysilicon surface to decrease the etch rate of the polysilicon.

Experiments with the inventive H₂ addition have been found to increase the Al₂O₃ to polysilicon selectivity to be greater than 3:1, more preferably greater than 5:1. One experiment found a selectivity of 48.7:1.

Experiments with the inventive H₂ addition have been found to increase etch rate of between 50-200 Å/minute. More preferably, the inventive high constant layer etch is able to provide and etch rate of between 100-1000 Å/minute. In one experiment an etch rate of 696 Å/minute of the high k dielectric was achieved. Experiments have found that the H₂ addition provided a 7% increase in Al₂O₃ and a 50% increase in selectivity. The selectivity increase with H2 addition is expected even more if VDC is low.

The invention also unexpectedly provides good etch uniformity. The invention provides a selective etch of a high k dielectric with respect to a silicon based material. Preferably, the silicon based material is at least one of silicon, such as crystalline silicon and polysilicon, and silicon nitride. More preferably, the silicon based material is silicon, such as crystalline silicon on polysilicon. A low selectivity has been found for silicon oxide. Preferably, the high k dielectric is binary metal oxide.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, modifications, and various substitute equivalents as fall within the true spirit and scope of the present invention.

What is claimed is:

1. A method for selectively etching a high k layer with respect to a silicon based material, comprising:
placing the high k layer into an etch chamber;
providing an etchant gas into the etch chamber, wherein the etchant gas comprises H₂; and
generating a plasma from the etchant gas to selectively etch the high k layer with respect to the silicon based material.

2. The method, as recited in claim 1, wherein the high k dielectric layer is an oxide layer.

3. The method, as recited in claim 2, wherein the etchant gas further comprises a halogen containing component.

4. The method, as recited in claim 3, wherein the etchant gas further comprises a noble gas.

5. The method, as recited in claim 1, wherein the etchant gas further comprises BCl₃ and an inert gas.

6. The method, as recited in claim 5, wherein the etchant gas has a volume H₂ to BCl₃ flow ration between 0.2-5:1.

7. The method, as recited in claim 6, wherein the etchant gas has a volume inert gas flow of less than 500 sccm.

8. The method, as recited in claim 7, wherein the etchant gas further comprises Cl₂.

9. The method, as recited in claim 8, wherein the etchant gas has a volume Cl₂ to BCl₃ flow ratio between 0-0.5:1.

10. The method, as recited in claim 1, wherein the etchant gas further comprises BCl₃ and Cl₂.

11. The method, as recited in claim 10, wherein the etchant gas has a volume H₂ to BCl₃ flow ration between 0.2-5:1.

12. The method, as recited in claim 11, wherein the etchant gas has a volume Cl₂ to BCl₃ flow ratio between 0-0.5:1.

13. The method, as recited in claim 12, wherein the silicon based material is at least one of silicon and silicon nitride and wherein the high k layer is at least one of Hf silicate, HfO₂, Zr silicate, ZrO₂, Al₂O₃, La₂O₃, SrTiO₃, SrZrO₃, TiO₂, and Y₂O₃.

14. The method, as recited in claim 13, wherein the silicon based material forms a layer, further comprising etching the silicon based material layer subsequent to selectively etching the high k layer.

15. A semiconductor devices formed by the method of claim 1.

16. A method for etching a stack with a high k layer over a silicon based layer, comprising:
placing the stack into an etch chamber;
selectively etching the high k layer with respect to the silicon based layer, comprising:
providing a high k layer etchant gas into the etch chamber, wherein the high k layer etchant gas comprises H₂; and
generating a plasma from the high k layer etchant gas to selectively etch the high k layer with respect to the silicon based layer;
stopping the selectively etching the high k layer; and
selectively etching the silicon based layer with respect to the high k layer.

17. The method, as recited in claim 16, wherein the high k layer etchant gas further comprises BCl₃ and Cl₂ and wherein the silicon based layer is formed of a silicon based material comprising at least one of silicon and silicon nitride.

18. The method, as recited in claim 17, wherein the high k layer etchant gas has a volume H₂ to BCl₃ flow ration between 0.2-5:1 and wherein the silicon based material is silicon.

19. The method, as recited in claim 18, wherein the high k layer etchant gas has a volume Cl₂ to BCl₃ flow ratio between 0-0.5:1.

20. An apparatus for forming flash memory with a high k dielectric layer over a silicon based layer, comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising;
an H₂ gas source;
a BCl₃ gas source; and
a Cl₂ gas source;
a controller controllably connected to the gas source and the at least one electrode, comprising:
at least one processor; and
computer readable media comprising:
computer readable code for selectively etching the high k layer with respect to the silicon based layer, comprising:
computer readable code for providing H₂ from the H₂ gas source;
computer readable code for providing BCl₃ from the BCl₃ gas source;
computer readable code for providing Cl₂ from the Cl₂ gas source; and
computer readable code for generating a plasma from the H₂, BCl₃, and Cl₂ to selectively etch the high k layer with respect to the silicon based layer;
computer readable code to stop the selectively etching the high k layer with respect to the silicon based layer; and
computer readable code for selectively etching the silicon based with respect to the high k layer.
